(19) United States
(12) Patent Application Publication
(10) Pub. No.: US 2004/0227106 A1
(43) Pub. Date: Nov. 18, 2004

(54) System and methods for ion beam containment using localized electrostatic fields in an ion beam passageway

(76) Inventor: Alfred M. Halling, Wenham, MA (US)

Correspondence Address: ESCHWEILER & ASSOCIATES, LLC, NATIONAL CITY BANK BUILDING, 629 EUCLID AVE., SUITE 1210, CLEVELAND, OH, 44114, US

(21) Appl. No.: 10/843,858

(22) Filed: May 12, 2004

Related U.S. Application Data
(60) Provisional application No. 60/470,009, filed on May 13, 2003.

(51) Int. Cl. H01J 37/317

(52) U.S. Cl. 250/492.21

(57) ABSTRACT

Ion implantation systems and beam confinement apparatus therefor are disclosed for inhibiting electron loss to a beam passageway sidewall, comprising a negatively biased conductive member to generate an electrostatic field repelling electrons away from the sidewall and a grounded conductive member between the sidewall and the ion beam to localize the electrostatic field to regions of the passageway away from the ion beam to avoid or mitigate adverse impact to the ion beam. Methods are disclosed for inhibiting electron loss to a sidewall in an ion beam transport passageway, comprising providing an electrostatic field in the passageway to repel electrons away from the sidewall, and localizing the electrostatic field to regions of the passageway away from an ion beam so as to repel electrons away from the sidewall without significant adverse impact to the ion beam.

### REFERENCE TO RELATED APPLICATION

This application claims priority to and the benefit of U.S. Provisional Patent Application Serial No. 60/470,009, which was filed May 13, 2003, entitled SYSTEM AND METHODS FOR ION BEAM CONTAINMENT USING LOCALIZED ELECTROSTATIC FIELDS IN AN ION BEAM PASSAGEWAY, the entirety of which is hereby incorporated by reference as if fully set forth herein.

### FIELD OF THE INVENTION

The present invention relates generally to ion implantation systems, and more particularly to improved methods and apparatus for ion beam containment using localized electrostatic fields in an ion implantation system.

### BACKGROUND OF THE INVENTION

In the manufacture of semiconductor devices, ion implantation is used to dope semiconductors with impurities. Ion beam implanters or ion implantation systems are employed to treat silicon wafers with an ion beam, so as to produce n or p type doped regions or to form passivation layers during fabrication of integrated circuits. When used for doping semiconductors, the ion implantation system injects a selected ion species to produce the desired extrinsic material. Implanting ions generated from source materials such as antimony, arsenic or phosphorus results in n type extrinsic material wafers, whereas if p type extrinsic material wafers are desired, ions generated with source materials such as boron, gallium or indium may be implanted. Ion implantation systems typically include an ion source for generating positively charged ions from such ionizable source materials. The generated ions are extracted from the source and formed into an ion beam, which is directed along a predetermined beam path in a beamline assembly to an implantation station, sometimes referred to as an end station. The ion implantation system may include beam forming and shaping structures extending between the ion source and the end station, which maintain the ion beam and bound an elongated interior cavity or passageway through which the beam is transported en route to one or more wafers or workpieces supported in the end station. The ion beam transport passageway is typically evacuated to reduce the probability of ions being deflected from the predetermined beam path through collisions with air molecules.

The charge-to-mass ratio of an ion affects the degree to which it is accelerated both axially and transversely by an electrostatic or magnetic field. Ion implantation systems typically include a mass analyzer in the beamline assembly downstream of the ion source, having a mass analysis magnet creating a dipole magnetic field across the beam path in the passageway. This dipole field operates to deflect various ions in the ion beam via magnetic deflection in an arcuate section of the passageway, which effectively separates ions of different charge-to-mass ratios. The process of selectively separating ions of desired and undesired charge-to-mass ratios is referred to as mass analysis. In this manner, the beam imparted on the wafer can be made very pure since ions of undesirable molecular weight will be deflected to positions away from the beam path and implantation of other than desired materials can be avoided.

High energy ion implantation is commonly employed for deeper implants in a semiconductor wafer. Conversely, high current, low energy ion beams are typically employed for shallow depth ion implantation, in which case the lower energy of the ions commonly causes difficulties in maintaining convergence of the ion beam. In particular, high current, low energy ion beams typically include a high concentration of similarly charged (positive) ions which tend to diverge due to mutual repulsion, a space charge effect sometimes referred to as beam blowup. Beam blowup is particularly troublesome in high current, low energy applications because the high concentration of ions in the beam (high current) exaggerates the force of the mutual repulsion of the ions, while the low propagation velocity (low energy) of the ions expose them to these mutually repulsive forces for longer times than in high energy applications. Space Charge Neutralization is a technique for reducing the space charge effect in an ion implanter through provision and/or creation of a beam plasma, comprising positively and negatively charged particles as well as neutral particles, wherein the charge density of the positively and negatively charged particles within the space occupied by the beam are generally equal. For example, a beam plasma may be created when the positively charged ion beam interacts with residual background gas atoms, thereby producing ion electron pairs through ionizing collisions during beam transport. As a result, the ion beam becomes partially neutralized through interaction with the background residual gas in the beam path.

In the case of high energy ion implantation, the ion beam typically propagates through a weak plasma that is a byproduct of the beam interactions with the residual or background gas. This plasma tends to neutralize the space charge caused by the ion beam by providing negatively charged electrons along the beam path in the passageway, thereby largely eliminating transverse electric fields that would otherwise disperse or blow up the beam. However, at low ion beam energies, the probability of ionizing collisions with the background gas is very low. Also, in the dipole magnetic field of a mass analyzer, plasma diffusion across magnetic field lines is greatly reduced while the diffusion along the direction of the field is unrestricted. Consequently, introduction of additional plasma to improve low energy beam containment in a mass analyzer is largely futile, since the introduced plasma is quickly diverted along the dipole magnetic field lines to the passageway sidewalls. Furthermore, low energy implantation systems typically suffer from electrons being lost to the sidewalls along the beamline assembly, which reduces the number of such electrons available for space charge neutralization. Thus, improvements in space charge neutralization can be effected by both the introduction of low energy electrons into the beam passageway, and by reducing the number or likelihood of electrons leaving or being lost to the sidewalls. Thus, there remains a need for improved ion implantation systems and apparatus therefor, to enhance ion beam containment, particularly for use with high current, low energy ion beams, by which electron loss can be mitigated to enhance space charge neutralization and prevent or reduce beam blowup.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later. The invention relates to improved ion implantation systems and beam containment apparatus therefor, as well as methodologies for improving beam containment in the transportation of implantation ion beams along a passageway, in which loss of neutralizing electrons to one or more sidewalls of the passageway is reduced or mitigated using localized electrostatic fields to facilitate space charge neutralization. Improved space charge neutralization, in turn, reduces the likelihood of ion beam blowup during transport through the system toward the end station. The invention finds utility in association with any type of ion implantation system, particularly in low energy implantation applications.

In one aspect of the invention, ion implantation systems and beam containment apparatus therefor are provided, where the beam containment apparatus may be located in a beamline assembly passageway, such as in the mass analyzer or downstream thereof, where the beam containment apparatus inhibits electron loss to the passageway sidewalls along at least a portion of a beam path. The beam containment apparatus comprises a conductive structure or member held at a first voltage to generate an electrostatic field sufficiently strong to repel electrons away from the sidewall and another conductive structure or member held at a second voltage between the sidewall and the ion beam to localize the electrostatic field to regions of the passageway away from the ion beam to avoid or mitigate adverse impact to the ion beam.

In one implementation, the beam containment apparatus comprises a first conductive member spaced inwardly from an interior surface of the passageway sidewall toward an ion beam and spaced from the ion beam between the sidewall interior surface and the ion beam. A second conductive member is located between the first conductive member and the ion beam to cover one or more portions of the first conductive member and to expose other portions thereof to the ion beam. One of the first and second conductive members is biased, such as by a negative voltage, and the other is grounded to produce an electrostatic field substantially localized to regions of the passageway away from the ion beam. The localized electrostatic field produced by the beam containment apparatus operates to repel electrons away from the sidewall without significant adverse impact to the ion beam. In another exemplary implementation, the sidewall is grounded, the first conductive member is negatively biased, and the second conductive member is positively biased.

In another aspect of the invention, methods are provided for inhibiting electron loss to a sidewall in an ion beam transport passageway, comprising providing an electrostatic field in the passageway to repel electrons away from the sidewall, and localizing the electrostatic field to regions of the passageway away from an ion beam so as to repel electrons away from the sidewall without significant adverse impact to the ion beam. The various aspects of the invention may thus be employed to provide improved quality of the beam plasma, and hence improved ion beam transmission.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a simplified schematic diagram illustrating an exemplary low energy ion implantation system having beam containment apparatus in accordance with an aspect of the present invention;

FIG. 2A is a detailed side elevation view in section illustrating another exemplary low energy ion implantation system having beam containment apparatus according to the invention;

FIG. 2B is a simplified side elevation view further illustrating a resolver in the exemplary system of FIG. 2A having beam containment apparatus according to the invention;

FIG. 3A is a side elevation view in section taken along line 3-3 of FIG. 2B illustrating an exemplary beam containment apparatus for repelling electrons away from four sidewalls in the resolver of FIGS. 2A and 2B wherein a first outer conductive member is negatively biased, a second inner conductive member is grounded, and the resolver housing sidewalls are grounded according to an aspect of the invention;

FIG. 3B is a side elevation view in section taken along line 3-3 of FIG. 2B illustrating another exemplary beam containment apparatus for repelling electrons away from upper and lower sidewalls in the resolver of FIGS. 2A and 2B according to the invention;

FIG. 3C is a side elevation view in section taken along line 3-3 of FIG. 2B illustrating still another exemplary beam containment apparatus for repelling electrons away from an upper sidewall in the resolver of FIGS. 2A and 2B according to the invention;

FIG. 3D is a side elevation view in section taken along line 3-3 of FIG. 2B illustrating yet another exemplary beam containment apparatus for repelling electrons away from four sidewalls in the resolver of FIGS. 2A and 2B according to the invention;

FIG. 4A is a top plan view in section taken along line 44 of FIG. 3B illustrating exemplary first and second conductive members of the beam containment apparatus in FIG. 3B, wherein the second conductive member comprises a mesh structure according to the invention;

FIG. 4B is a top plan view in section taken along line 4-4 of FIG. 3B illustrating another example of first and second conductive members of the beam containment apparatus in FIG. 3B, wherein the second conductive member comprises a plurality of elongated slots according to the invention;

FIG. 4C is a top plan view in section taken along line 4-4 of FIG. 3B illustrating yet another example of first and second conductive members of the beam containment apparatus in FIG. 3B, wherein the second conductive member comprises a plurality of generally circular holes or apertures according to the invention;

FIG. 4D is a top plan view in section taken along line 4-4 of FIG. 3B illustrating yet another example of first and second conductive members of the beam containment apparatus in FIG. 3B, wherein the second conductive member comprises a plurality of mutually parallel conductive wires according to the invention;

FIGS. 5A and 5B are partial side elevation views in section taken along line 5-5 of FIG. 4B further illustrating the exemplary beam confinement apparatus of FIG. 3B using a second conductive member having a plurality of elongated slots according to the invention and exemplary localized electrostatic fields associated therewith;

FIG. 5C is a partial side elevation view in section taken along line 5-5 of FIG. 4B further illustrating exemplary electron tracking results in the beam confinement apparatus of FIG. 3B using a second conductive member having a plurality of elongated slots according to the invention;

FIG. 5D is a partial side elevation view in section taken along line 5-5 of FIG. 4B further illustrating exemplary electric field magnitude in the beam confinement apparatus of FIG. 3B using a second conductive member having a plurality of elongated slots according to the invention;

FIGS. 6A and 6B are partial side elevation views in section taken along line 6-6 of FIG. 4D further illustrating the exemplary beam confinement apparatus of FIG. 3B using a second conductive member comprising a plurality of parallel wires and exemplary localized electrostatic fields associated therewith in accordance with the invention;

FIG. 7A is a side elevation view in section taken along line 3-3 of FIG. 2B illustrating another implementation of the exemplary beam containment apparatus for repelling electrons away from four sidewalls in the resolver of FIGS. 2A and 2B wherein a first outer conductive member is negatively biased, a second inner conductive member is positively biased, and the resolver housing sidewalls are grounded according to an aspect of the invention;

FIG. 7B is a side elevation view in section taken along line 3-3 of FIG. 2B illustrating another exemplary beam containment apparatus for repelling electrons away from upper and lower sidewalls in the resolver of FIGS. 2A and 2B according to the invention;

FIG. 7C is a side elevation view in section taken along line 3-3 of FIG. 2B illustrating still another exemplary beam containment apparatus for repelling electrons away from an upper sidewall in the resolver of FIGS. 2A and 2B according to the invention;

FIG. 7D is a side elevation view in section taken along line 3-3 of FIG. 2B illustrating yet another exemplary beam containment apparatus for repelling electrons away from four sidewalls in the resolver of FIGS. 2A and 2B according to the invention;

FIGS. 8A and 8B are partial side elevation views in section taken along line 8-8 of FIG. 4D further illustrating the exemplary beam confinement apparatus of FIG. 7B using a second conductive member comprising a plurality of parallel wires and exemplary localized electrostatic fields associated therewith in accordance with the invention;

FIGS. 9A-9C are side elevation views in section taken along line 3-3 of FIG. 2B illustrating several other exemplary beam containment apparatus for repelling electrons away from one or more grounded sidewalls in the resolver of FIGS. 2A and 2B, wherein the housing is grounded and a single second conductive member is negatively biased according to the invention; and

FIG. 10 is a flow diagram illustrating an exemplary method of inhibiting electron loss to a sidewall in an ion beam transport passageway in accordance with still another aspect of the invention.

### DETAILED DESCRIPTION OF THE INVENTION

The present invention will now be described with reference to the drawings wherein like reference numerals are used to refer to like elements throughout. The present invention provides methods and apparatus for improving or facilitating ion beam containment through increased retention of electrons in a beam transport passageway, which enhances space charge neutralization. The electron retention is improved by generating an electrostatic field using one or more conductive structure or member spaced inwardly from one or more passageway sidewall interior surfaces, and localizing the electrostatic field strength to the periphery of the passageway. This provides a cusp electric field strength at the periphery to repel the majority of electrons away from the passageway sidewalls, while minimizing the electrostatic field's effect on the ion beam at the center of the passageway.

Various exemplary implementations are illustrated and described hereinafter in the context of beam containment apparatus located in a resolver housing downstream of a mass analyzer in a beamline assembly. However, it will be appreciated that the invention may be advantageously employed in applications other than those illustrated and described herein, for example, wherein the beam containment apparatus may be situated anywhere along the beam path between the ion source and the end station. In addition, it is noted that while illustrated and described below in conjunction with a low energy ion implantation system, the various aspects of the present invention may be carried out in association with high energy implanters, such as those including linear accelerator devices, where beam containment apparatus may be situated within or proximate such devices, within a mass analyzer device, and/or within other devices in a beamline assembly or in drift regions along a beam transport passageway in the implanter.

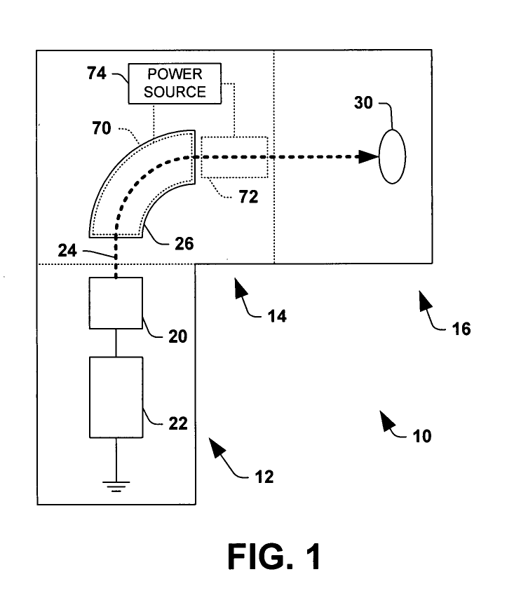

Referring initially to FIG. 1, a simplified low energy ion implantation system 10 is schematically illustrated, having a terminal 12, a beamline assembly 14, and an end station 16. The terminal 12 comprises an ion source 20 powered by a high voltage power supply 22. The ion source 20 produces an ion beam 24 that is directed to the beamline assembly 14. The ion beam 24 is conditioned by a mass analyzer 26 in the beamline assembly 14, wherein a dipole magnetic field is established in the mass analyzer 26 to pass only ions of appropriate charge-to-mass ratio to the end station 16. The end station 16 may be any type of end station, such as a serial end station operative to support a single wafer workpiece 30 or a batch end station adapted to support multiple wafers 30 for concurrent implantation, wherein the conditioned ion beam 24 is directed toward the target wafer 30 in the end station 16.

In accordance with the invention, the system 10 also comprises ion beam confinement apparatus 70 and/or 72 within the beamline assembly 14 to promote ion beam space charge neutralization and thus to reduce the likelihood of blowup of the ion beam 24 during transmission through the system 10. In the illustrated example, the system 10 comprises confinement apparatus 70 in the mass analyzer 26 and/or confinement apparatus 72 downstream of the mass analyzer 26 along the path of the ion beam 24, where the apparatus 70, 72 is coupled with a power source 74. However, beam containment apparatus may be provided anywhere along the path of the ion beam 24 in accordance with the present invention to inhibit electron loss to the sidewalls of a ion beam transport passageway in the implanter 10. The apparatus 70, 72, as well as other beam containment apparatus illustrated and described below, operate to create an electrostatic field localized to the peripheral regions along the beam path without significant adverse impact to the beam 24 itself, where the field is generated by negatively biasing a conductive member and field localization is provided by grounding another conductive member.

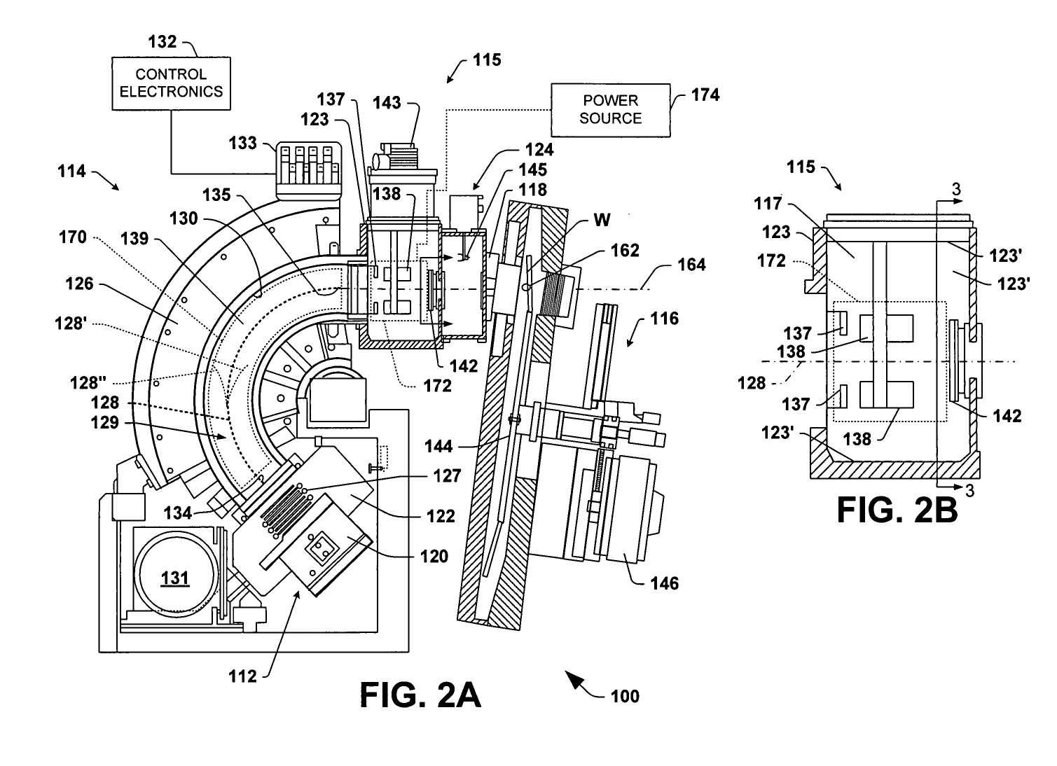

In FIGS. 2A and 2B, another exemplary ion implantation system 100 is illustrated in greater detail in accordance with one or more aspects of the invention. The system 100 comprises an ion source 112, a beamline assembly 114 with a mass analyzer 126, a resolver 115, and a beam neutralizer 124, as well as a target or end station 116, where an expansible bellows assembly 118 permits movement of the end station 116 with respect to the beamline assembly 114 and connects the end station 116 and the beamline assembly 114. Although FIG. 2A illustrates a low energy batch ion implanter 100, the present invention has applications in high energy and other types of implanters as well, having serial or batch type end stations and/or linear accelerator components (not shown). The exemplary ion source 112 comprises a plasma chamber 120 and an ion extractor assembly 122. Energy is imparted to an ionizable dopant gas to generate ions within the plasma chamber 120. Generally, positive ions are generated, although the present invention is applicable to systems wherein negative ions are generated by the source 112. The positive ions are extracted through a slit in the plasma chamber 120 by the ion extractor assembly 122, which comprises a plurality of extraction electrodes 127. The ion extractor assembly 122 thus extracts a beam 128 of positive ions from the plasma chamber 120 and accelerates the extracted ions along a beam path toward the mass analyzer 126 in the beamline assembly 114.

The mass analyzer 126 functions to pass only ions of an appropriate charge-to-mass ratio to the resolver 115 having a resolver housing 123, and thereafter to a beam neutralizer 124. The mass analyzer 126 provides a curved beam path 129 within a passageway 139 defined by an aluminum beam guide having side walls 130, where the passageway 139 is evacuated by a vacuum pump 131. The ion beam 128 that propagates along the path 129 is affected by a dipole magnetic field generated by the mass analyzer magnet 126, so as to reject ions of an inappropriate charge-to-mass ratio. The strength and orientation of this dipole magnetic field is controlled by control electronics 132 which adjust the electrical current through the field windings of the magnet 126 through a magnet connector 133. The dipole magnetic field causes the ion beam 128 to move along the curved beam path 129 from a first or entrance trajectory 134 near the ion source 112 to a second or exit trajectory 135 near the resolver housing 123. Portions 128′ and 128″ of the beam 128, are comprised of ions having an inappropriate or undesired charge-to-mass ratio, which are deflected away from the curved trajectory 129 and into the passageway sidewalls 130. In this manner, the magnet 126 passes only those ions in the beam 128 which have the desired charge-to-mass ratio to the resolver 115.

The beamline assembly 114 further comprises a first beam confinement apparatus 170 located in the mass analyzer 126 and/or a second beam confinement apparatus 172 located downstream of the mass analyzer 126 in the resolver 115, both of which may be powered by a DC power source 174 for generation of an electrostatic field in the beam transport passageway as described further below. In the following discussion and figures, the details of the exemplary confinement apparatus 172 are set forth, although it is to be appreciated that other beam confinement apparatus are contemplated as within the scope of the invention having differing structures and in different locations than the exemplary apparatus 172 in the resolver 115. The exemplary resolver housing 123 comprises a terminal electrode 137, an electrostatic lens 138 for focusing the ion beam 128, and a dosimetry indicator such as a Flag Faraday 142. The beam neutralizer 124 comprises a plasma shower 145 for neutralizing the positive charge that would otherwise accumulate on a target wafer W in the end station 116 as a result of implantation by the positively charged ion beam 128. The beam neutralizer 124 and the resolver 115 are evacuated by a vacuum pump 143.

The end station 116 is located downstream of the beam neutralizer 124, comprising a disk-shaped wafer support 144 upon which wafers W are mounted for implantation. The wafer support 144 resides in a target plane which is generally perpendicularly oriented to the direction of the implant beam and is rotated by a motor 146. The ion beam 128 is thus imparted on wafers W mounted to the support 144 as they move in a circular path at a point 162, which is the intersection of the final generally straight portion 164 of the ion beam path and the wafer W, wherein the target plane is adjustable about this point 162. Although illustrated in association with the exemplary batch end station 116, the invention may be implemented in conjunction with systems having other types of end stations, for example, such as serial implanters for implanting a single wafer W at a time.

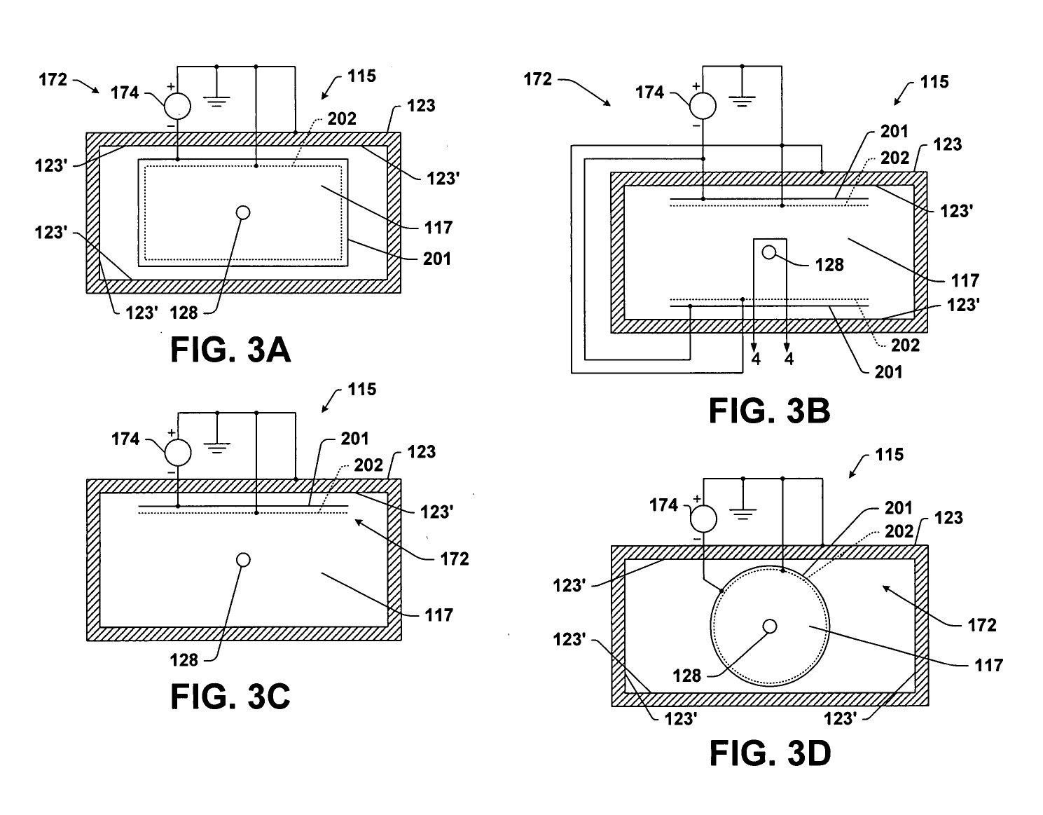

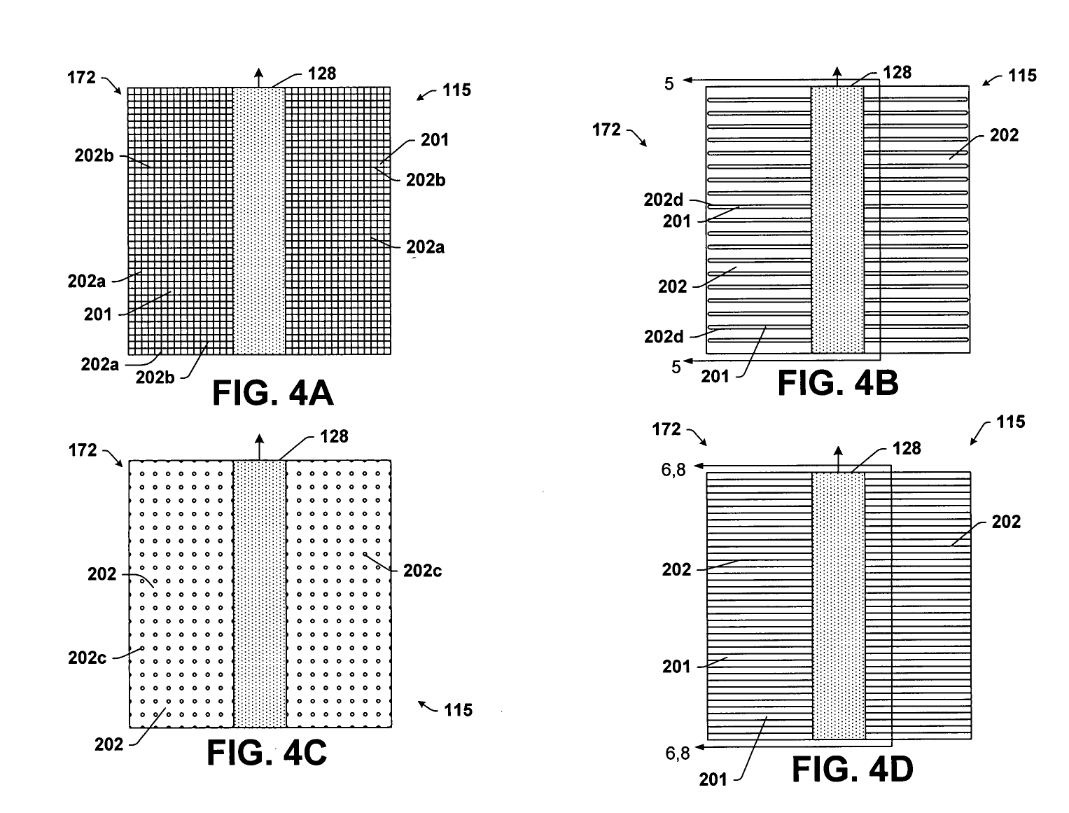

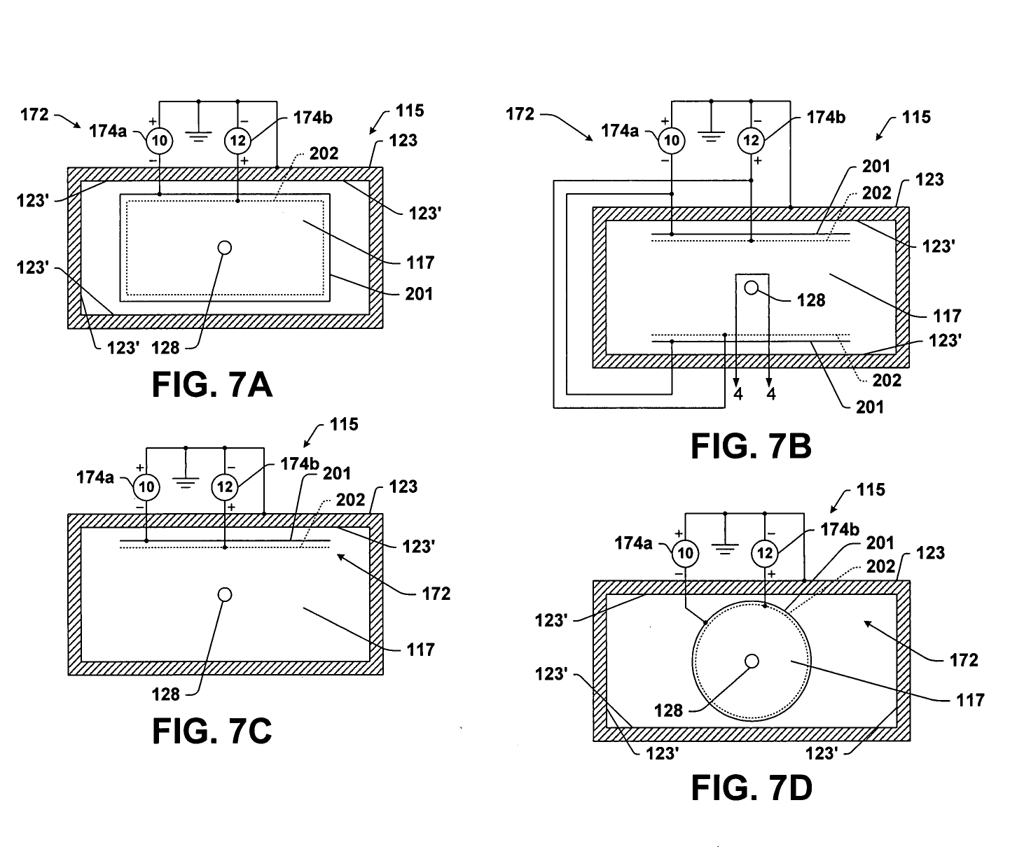

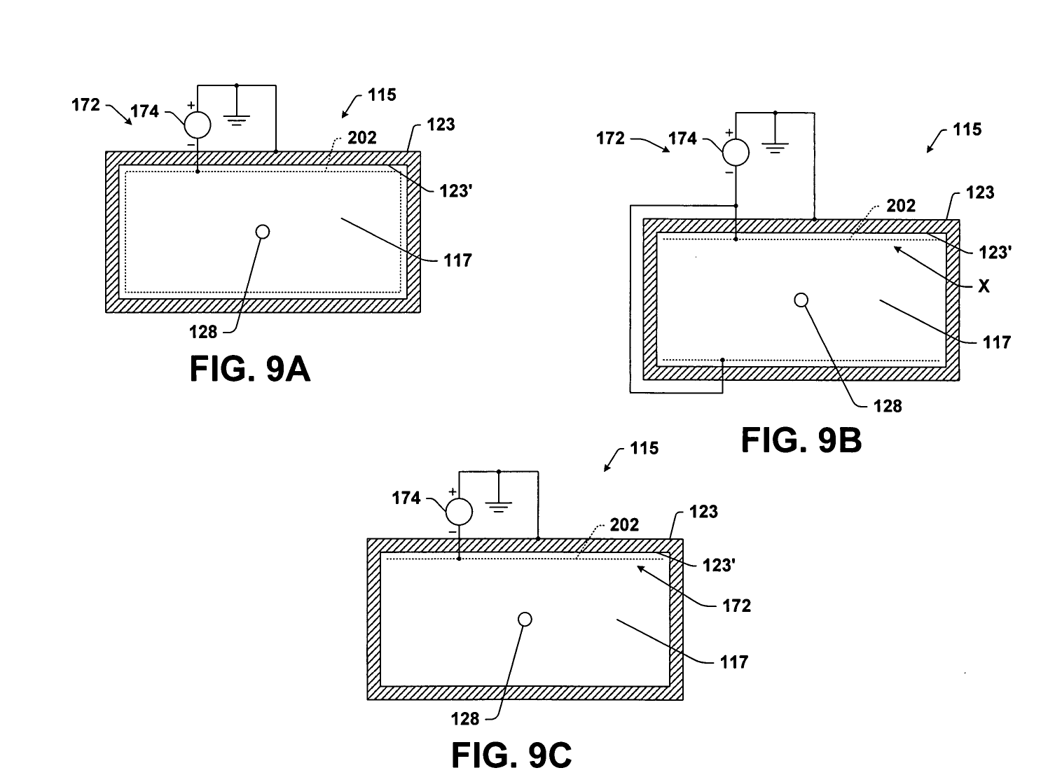

Several exemplary implementations of the ion beam confinement apparatus 172 in the resolver 115 are illustrated and described below with respect to FIGS. 3A-3D taken along line 3-3 in FIG. 2B, in which a first outer conductive member 201 is negatively biased, a second inner conductive member 202 is grounded, and the resolver housing sidewalls 123 are grounded according to an aspect of the invention. Other possible implementations of the apparatus 172 are shown in FIGS. 7A-7D, wherein the first member 201 is at a negative voltage, the second member 201 is at a positive voltage, and the housing is grounded. Further possible implementations are illustrated in FIGS. 9A-9C, wherein no first member is used, in which the sidewall is grounded, and the second conductive member is negatively biased. FIGS. 4A-4D illustrate several exemplary implementations of the second conductive member, wherein other forms and shapes of second conductive member may be used, and wherein any of the second conductive members 202 may be employed in any of the various configurations of the apparatus 172 within the scope of the invention. These figures are used to give only a few of the many ways that two electrodes can be used to form a very fine “cusp” electric field near the walls of the beam guide. This invention contemplates any method and/or apparatus that creates a localized electric field near the wall that has no significant strength in the region of the beam, wherein the exemplary implementations illustrated and described below provide “cusp” shaped fields near the sidewalls wherein the field seen by electrons near the sidewall has an alternating characteristic, and wherein the alternating cusps can be spaced by any suitable distance, for example, as close together as can be mechanically created.

The exemplary resolver 115 of FIGS. 2A and 2B forms part of the beamline assembly 114 located downstream from the ion source 112 and the mass analyzer 126, whereby a portion of the ion beam transport passageway 117 is defined by inner or interior surfaces 123′ of the sidewalls of the resolver housing 123, where the interior surfaces 123′ are spaced from the path of the ion beam 128. As used herein, passageway interior surfaces, such as those 123′ illustrated in the figures, include the innermost surfaces of the passageway, wherein the first and second conductive members of the invention are located inwardly therefrom, and are not recessed in the sidewalls. The beam containment apparatus 172 operates to inhibit electron loss to one or more of the resolver housing sidewalls 123 along at least a portion of the path in the resolver 115 without significant adverse impact on the ion beam 128 through creation and localization of electrostatic fields in the passageway 117.

FIG. 3A provides a simplified sectional side elevation view of the resolver 115 taken along line 3-3 of FIG. 2B illustrating an exemplary implementation of the containment apparatus 172 for repelling electrons away from all four sidewalls 123 in the resolver 115. In this example, the beam containment apparatus 172 comprises a first conductive member 201 extending along at least a portion of the passageway 117, where the first conductive member 201 is spaced inwardly from the interior surfaces 123′ of the housing 123 toward the ion beam 128 while also being spaced from the ion beam 128 between the sidewall interior surface 123′ and the ion beam 128. The apparatus 172 further comprises a second conductive member 202 located along the passageway 117 between the first conductive member 201 and the ion beam, where the second conductive member 202 is proximate to the first conductive member 201. In the illustrated example, the conductive members 201 and 202 comprise graphite, although any other conductive materials may be used, including but not limited to aluminum, wherein graphite is less likely to contribute to wafer contamination and is also not likely to melt during operation.

The second member 202 of the invention may be any suitable conductive structure that covers at least a first portion of the first member 201 such that the ion beam 128 effectively does not see (e.g., is not exposed to the effect of) the full potential of the covered portion, and also exposes at least a second portion of the first conductive member 201 in a region near the sidewalls. This structure provides for localization of the electric fields near the sidewalls 123 of the resolver 115 to redirect electrons away from the sidewalls 123 without adversely impacting the ion beam 128. In accordance with one aspect of the invention, the first member 201 in FIGS. 3A-3D is coupled with the power source 174 and negatively biased thereby, and the second member 202 is grounded to create an electrostatic field within the passageway 117. In addition, the housing sidewalls 123 are grounded in these examples, although not a strict requirement of the invention.

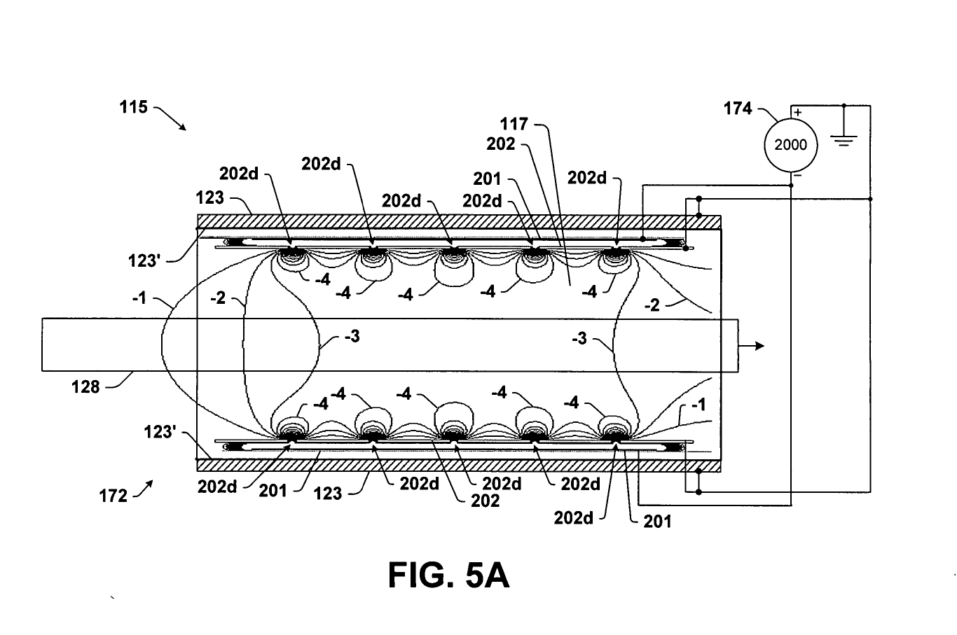

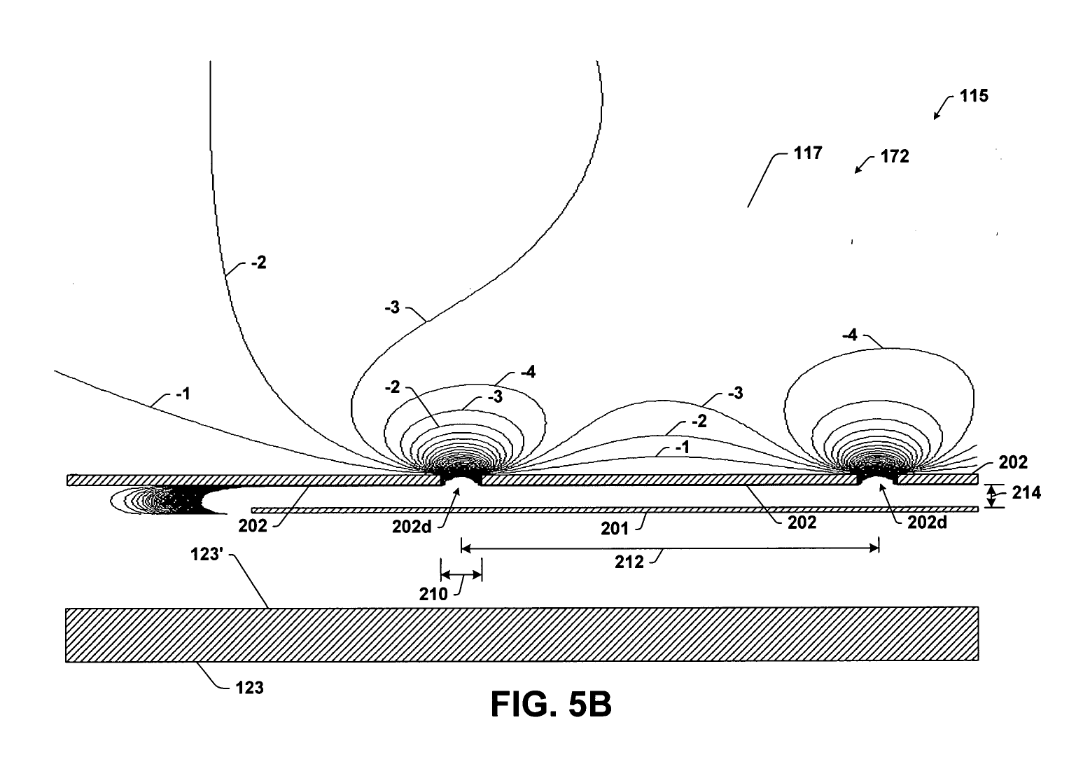

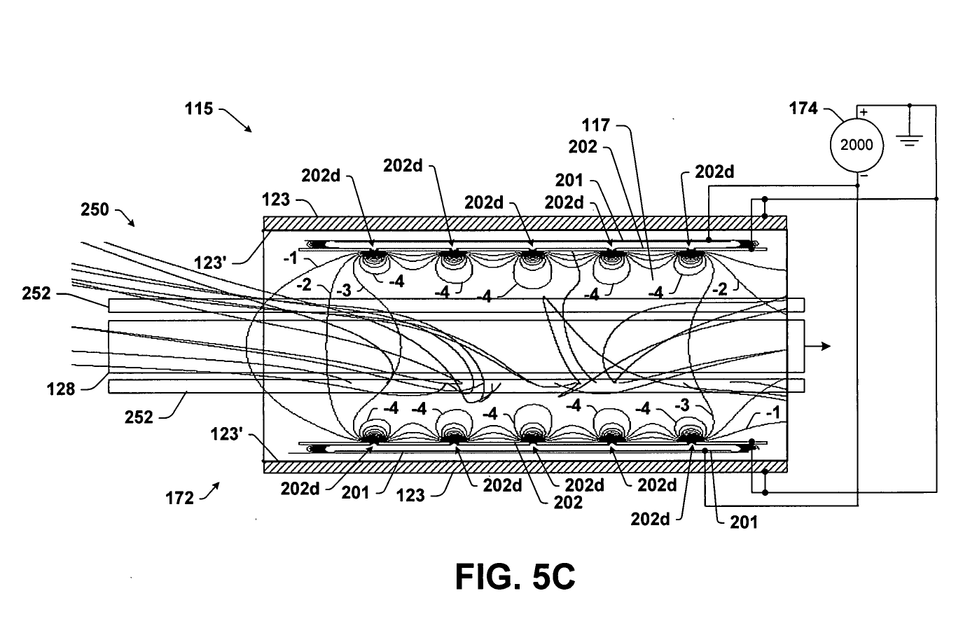

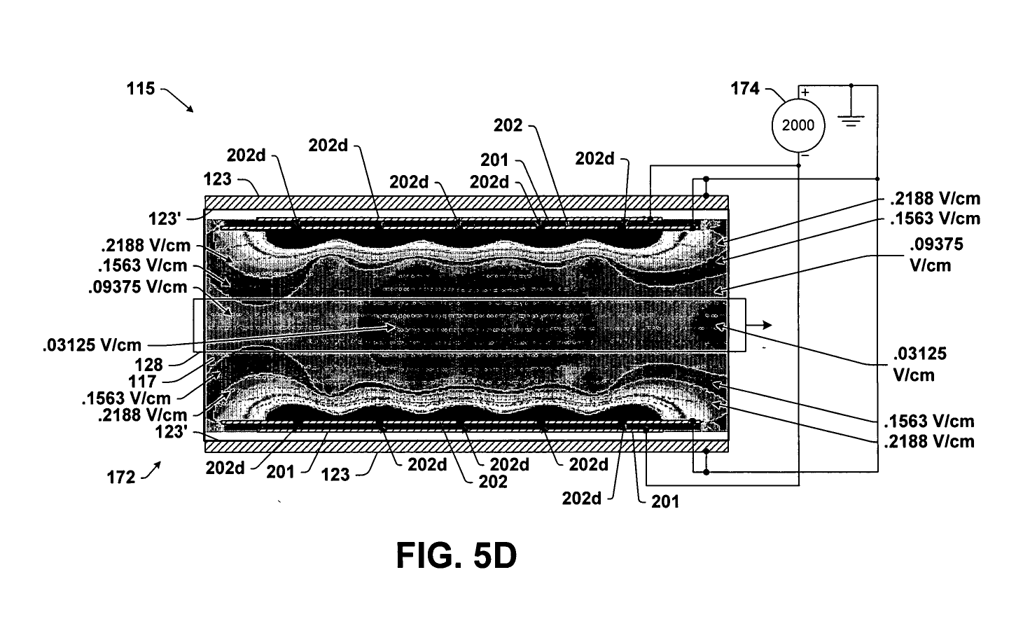

The electrostatic fields established by the negatively biased first member 201 cause electrons to be repelled away from the sidewalls of the housing 123, thereby enhancing or preventing degradation of ion beam space charge neutralization. The partial covering of the grounded first member 201 by the second member 202 localizes the electrostatic field to passageway regions away from the ion beam 128, so as to repel electrons away from the sidewalls without significant adverse impact to the ion beam 128, as illustrated further in FIGS. 5A-5C below. In this and other examples, the partial covering (e.g., and the partial exposure) of the biased first member 201 is achieved by provision of at least one opening in the second conductive member 202 exposing the second portion of the first conductive member 201 to the ion beam 128, wherein several examples of such openings are illustrated and described below with respect to FIGS. 4A-4D.

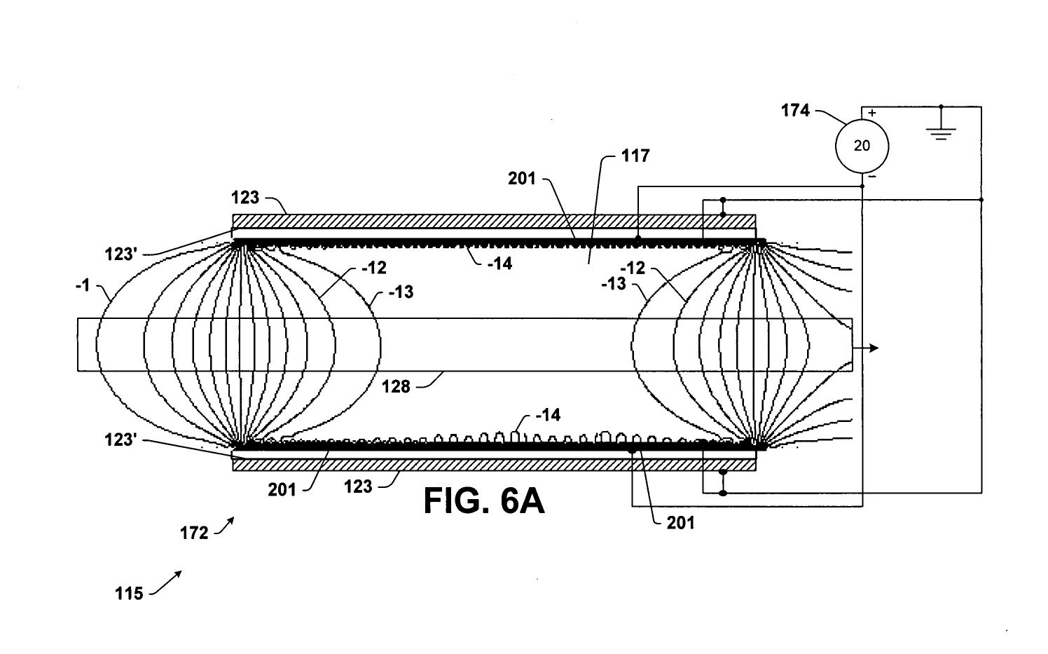

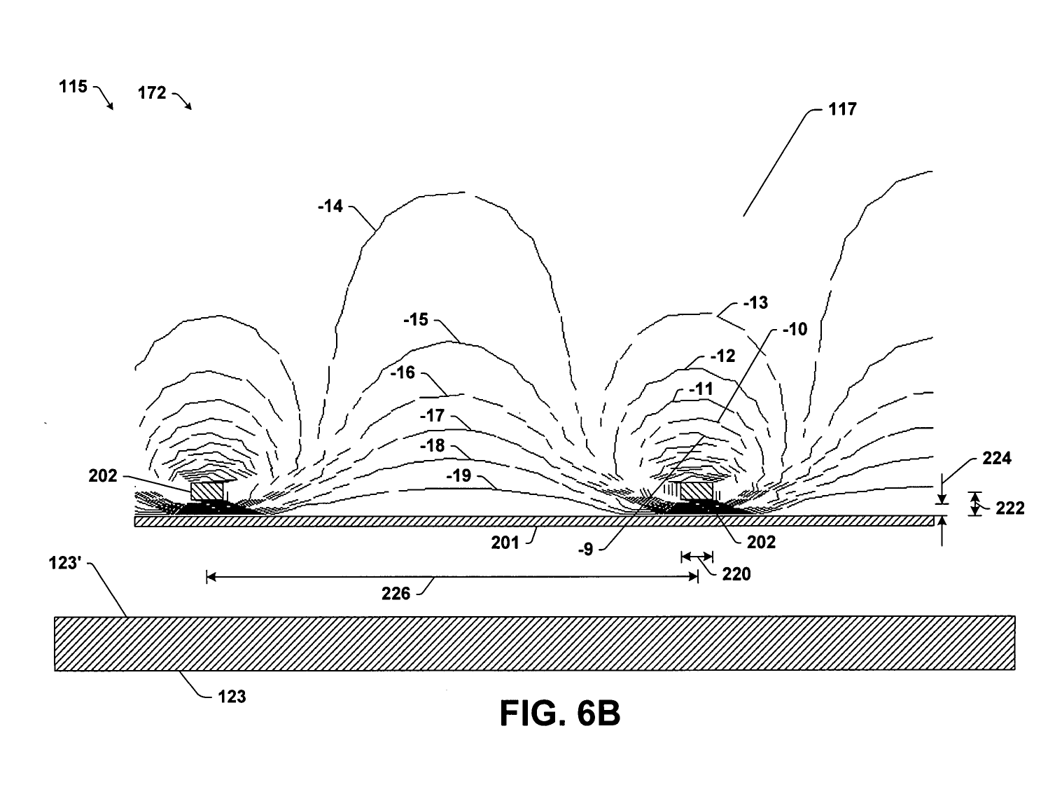

In the example of FIG. 3A, the exemplary beam containment apparatus 172 repels electrons away from four sidewalls in the resolver 115, wherein the negatively biased first (e.g., outer) conductive member 201 is generally continuous around the lateral periphery of the passageway 117. The grounded second (e.g., inner) conductive member 202 extends around the periphery and is spaced inwardly from the first member 201 to localize the field effect seen by the ion beam 128. In FIG. 3B, another example is illustrated for repelling electrons away from the upper and lower sidewalls in the resolver 115. FIGS. 4A-4C below illustrate several alternative implementations of the apparatus 172 of FIG. 3B, and FIGS. 5A-5C and 6A-6B illustrate exemplary electrostatic fields associated with implementations of the apparatus 172 of FIG. 3B using conductive second members 202 of FIGS. 4B and 4D, respectively. FIG. 3C provides a side elevation view of yet another possible beam containment apparatus 172 that repels electrons away from an upper sidewall in the resolver 115. Yet another possible implementation is shown in FIG. 3D, providing beam containment apparatus 172 encircling the beam path for repelling electrons away from the four resolver sidewalls. It is noted at this point that the configurations illustrated in FIGS. 3A-3D are exemplary in nature and are not exhaustive of the possibilities falling within the scope of the invention and the appended claims.

Referring now to FIGS. 2B, 3B, and 4A-4D, the second conductive member 202 may be implemented in a variety of fashions, some examples of which are depicted in the top plan views of FIGS. 4A-4D taken along line 4-4 in FIG. 3B. In the example of FIG. 4A, the second conductive member 202 comprises a screen or mesh structure having a first set of mutually parallel conductive wires 202a (vertically extending in the figure) spaced from one another, as well as a second set of mutually parallel conductive wires 202b (horizontally extending in the figure), also spaced from one another, providing a plurality of generally rectangular openings exposing portions of the first member 201 between adjacent conductive wires in the mesh structure, wherein the individual wires 202 of FIG. 4A may be round, rectangular, or any suitable shape within the scope of the invention. FIG. 4B illustrates another possible example of the second conductive member 202, comprising a conductive structure 202 with a plurality of slot shaped apertures 202d. As shown in FIG. 4C, another implementation provides a plurality of generally circular holes 202c through the second conductive member, the holes 202c individually exposing portions of the first conductive member 201 to the ion beam 128. FIG. 4D illustrates another possible second conductive member 202, comprising a plurality of mutually parallel conductive wires spaced from one another providing a plurality of spaces or openings therebetween to expose portions of the first member 201 between adjacent conductive wires, wherein the individual wires 202 of FIG. 4D may be round, rectangular, or any suitable shape within the scope of the invention.

Referring also to FIGS. 5A-5D, further details are illustrated for an implementation of the apparatus 172 of FIGS. 2B and 3B, using the second conductive member 202 of FIG. 4B comprising a conductive structure 202 with a plurality of slot shaped apertures 202d, wherein the first member 201 is negatively biased to about 2000 volts DC, the second member 202 is grounded, and the sidewalls 123 are grounded. FIGS. 5A-5D illustrate exemplary localized electrostatic fields generated by the apparatus 172, shown as equal potential lines in FIGS. 5A-5C and electrostatic field regions in FIG. 5D. In this example, a plurality of elongated slots 202d are provided through the second conductive member 202, individually exposing the beam 128 to portions of the first conductive member 201. As further illustrated in FIG. 5B, the individual slots 202d have a width 210 of about 5 mm and a length greater than the width, wherein the slots 202d are generally parallel to one another, and wherein adjacent slots 202d are spaced from one another by a pitch distance 212 about 50 mm or more, such as about 50 mm in the illustrated implementation. Further, the first and second conductive members 201 and 202 are spaced from one another by a gap distance 214 of about 1 mm.

It is noted that these dimensions and bias values are illustrative of but one implementation, and that structures having other dimensions and configurations are possible within the scope of the invention and the appended claims. In other possible implementations of the invention, the conductive members 201 and 202 could be too small to show in these figures and the complete structure would be too complex for conventional modeling software programs to yield accurate simulation results. In this regard, the openings 202d in the second member 202 may be of any shape and any dimension, wherein the illustrated shapes are merely examples. Moreover, it is noted that the structures illustrated and described herein are not necessarily drawn to scale.

As illustrated in FIGS. 3B and 5B, the beam confinement apparatus 172 may be operated by providing a negative voltage to the first conductive member 201 using the power source 174 and grounding the second member 202, wherein the sidewalls 123 are also grounded in this example. In one example, a negative DC bias voltage of several hundred volts or more (e.g., about −2000 volts) is applied to the first conductive member 201, with the second member 202 and the housing 123 being grounded. For this biasing condition, exemplary equal potential contours are illustrated in FIGS. 5A-5C and electric field regions are shown in FIG. 5D, wherein it is noted that the electric field amplitude decays rapidly from the second member 202 towards the center of the beam 128 for a resolver 115 in which the upper and lower second conductive members 202 are spaced about 400 mm from one another, wherein the field strength decreases by half roughly every slot width distance 210 (e.g., about 5 mm in this example).

Thus, it has been appreciated that the apparatus 172 of the invention provides electron repulsion fields which are localized to a degree not possible with macroscopic electrodes. Further, the employment of much wider electrodes and large electrode spacings do not minimize the electrostatic field effect on ions in the central regions of a passageway or beamguide, but rather operate essentially as an acceleration-deceleration-acceleration-deceleration column, which is known in the art to have a detrimental effect on beam transport. Thus, the invention provides significant performance advantages not achievable with large energized electrodes recessed into passageway walls in a dipole magnet passageway. Rather, certain implementations of the invention contemplate using relatively tiny electrodes spaced inwardly from the interior sidewall surfaces 123′ as in the mesh or wire configurations of FIGS. 4A and 4D, and small apertures or openings (e.g., slots, holes, or other openings) as in the apparatus of FIGS. 4B and 4C. In this regard, the cusp fields generated by the apparatus of the invention are preferably closely spaced so as to better localize the field effects to portions of the passageway 117 away from the ion beam 128 itself.

As can be seen in FIGS. 5A-5D, relatively strong repulsive electrostatic field strengths are provided near the second conductive member 202 to prevent loss of electrons to the peripheral sidewall surfaces 123′, while the field strength is relatively insignificant in the innermost regions of the passageway 117 through which the ion beam 128 travels. This aspect of the invention thereby provides for the electrostatic field strength at the ion beam 128 to be about two orders of magnitude smaller or less relative to that near the second conductive member 202, wherein the localization of the electrostatic fields is very great in the mid portion of the passageway 117 between the entrance and exit ends of the apparatus 172. In one implementation, the electrostatic field at the path of the ion beam 128 is about 0.1 V/cm or less. Other biasing values and dimensional variants are possible within the scope of the invention, wherein these parameters are adjusted for a given passageway size, or to tune other operational performance measures.

FIG. 5C illustrates several exemplary electron trajectories 250 through the apparatus 172 in the presence of the localized electrostatic fields of the invention. As can be seen in FIG. 5C, electrons generated at random angles from a region near the edge of the beam 128 initially encounter the localized fields of the apparatus 172 and are then redirected back into the plasma 252 that surrounds the beam 128. Thus, while certain electrons may penetrate the electrostatic fields of the apparatus 172, the majority are deflected away from the sidewalls 123 back toward the beam 128, thereby contributing to space charge neutralization in the passageway 117 and hence inhibiting beam blowup. It is noted in FIGS. 5A-5C that the electrostatic fields have only a marginal impact on the beam 128 at the entrance and exit ends of the apparatus 172, and further that the field localization is even more pronounced in the mid portions of the apparatus between the entrance and exit ends.

FIG. 5D further illustrates the exemplary localization of the electrostatic fields within the beam containment apparatus 172. In this example, the beam 128 generally encounters fields of less than 0.1 V/cm along the beam path due to the apparatus 172. Thus, in the center regions of the passageway 117, the fields associated with the charged ion beam 128 and the beam plasma are the dominant determinant of electron trajectories, wherein the electrons in the center regions are largely unaffected by the apparatus 172 and the fields thereof. However, as electrons travel outward toward the sidewalls 123, the fields of the beam containment apparatus 172 become much larger, whereby most if not all of the electrons are redirected back toward the beam, as shown in the exemplary electron trajectory traces of FIG. 5C.

FIGS. 6A and 6B illustrate another exemplary implementation of the apparatus 172 of FIGS. 2B and 3B and the associated electrostatic fields thereof, using a second conductive member 202 of FIG. 4D using a second conductive member comprising a plurality of parallel wires 202 and exemplary localized electrostatic fields associated therewith in accordance with the invention. As with the previous example, the apparatus 172 in FIGS. 6A and 6B employs a negatively biased first member 201 with the second member wires 202 and the housing 123 being grounded, wherein the first member 201 is negatively biased to about 20 volts DC. The conductive wires 202 are spaced from one another to provide a plurality of gaps between adjacent conductive wires 202 in the set, so as to cover first portions of the negatively biased first member 201 and to expose other portions thereof to the ion beam 128.

As shown in FIG. 6B, the wires 202 in this example are generally rectangular with a width dimension 220 of about 1 mm with the wire centers being spaced a similar distance 222 of about 1 mm from the grounded first member 201, wherein the closest portion of the wires are spaced a distance 224 of about 1 wire width dimension or less from the grounded first conductive member 201, such as about 1 mm or less, preferably about 0.5-1.0 mm. Moreover, the wires are spaced from one another by a distance 226, such as several wire widths in the illustrated case. As with the examples above, these dimensions are illustrative of but one possible implementation, wherein structures having other dimensions and configurations are possible within the scope of the invention and the appended claims, for example, wherein the wires 202 may alternatively be round. As illustrated in FIGS. 3B and 6A, the beam confinement apparatus 172 of this example may be operated by providing a negative voltage to the first conductive member 201 with the wires 202 grounded, wherein the housing 123 may, but need not, be grounded. For example, a negative DC bias voltage of about −20 volts DC may be applied to the first member 201.

FIGS. 6A and 6B show exemplary equal potential contours for this case, wherein it is noted that the field amplitude decays rapidly from the second member 202 towards the center of the beam 128, particularly in the mid portion of the apparatus 172 between the entrance and exit ends. As with the above example of FIGS. 5A-5C, the electrostatic field strength decreases in the direction from the second member 202 to the beam center by half roughly every spacing distance 224 (e.g., about 0.5-1.0 mm in this example), thereby providing electron repulsion fields which are localized to a degree not possible with widely spaced electrodes. In this regard, relatively strong repulsive electrostatic field strengths are provided near the second conductive member 202 to prevent loss of electrons to the peripheral interior sidewall surfaces 123′, while the field strength is relatively insignificant in the region of the passageway 117 through which the ion beam 128 travels. The invention has a further benefit in that extra electrons may be advantageously generated if beam strike events occur at the negatively biased first conductive member 201, wherein such generated electrons may further contribute to space charge neutralization to prevent or inhibit beam blowup.

As with the above examples, the implementation of FIGS. 6A and 6B provides for the electrostatic field strength at the beam 128 to be significantly less relative to that near the second conductive member 202. In one implementation, the electrostatic field at the ion beam is about 0.1 V/cm or less. It is noted that different biasing values and dimensions are possible within the scope of the invention, wherein these values may be adjusted for a given passageway size, or to tune other operational performance measures. It is further noted in FIG. 6A that beam ions entering the apparatus 172 may experience an acceleration of about 13 volts, and then are similarly decelerated as they exit the apparatus 172, wherein the beam containment apparatus 172 of FIGS. 6A and 6B may advantageously provide a small focusing effect that could be of benefit to the beam 128.

Referring now to FIGS. 2B, and 7A-8B, several other exemplary beam containment apparatus are illustrated within the scope of the invention, in which the sidewalls 123 are grounded, while the first conductive member 201 is negatively biased (e.g., negative 10 volts DC with respect to ground in one example), and the second conductive member 202 is positively biased (e.g., plus 12 volts in the illustrated implementation). Like the above examples, the apparatus 172 of FIGS. 7A-7D provide localized electrostatic fields near the sidewalls 123 while also reducing the field effect at the center of the passageway 117 near the ion beam 128. Four possible examples are illustrated in FIGS. 7A-7D, wherein the second conductive member 202 may be of any suitable form, such as those of FIGS. 4A-4C above or any conductive structure 202 that covers at least a first portion of the first conductive member 201 and exposes at least a second portion of the first conductive member 201 with respect to the ion beam 128.

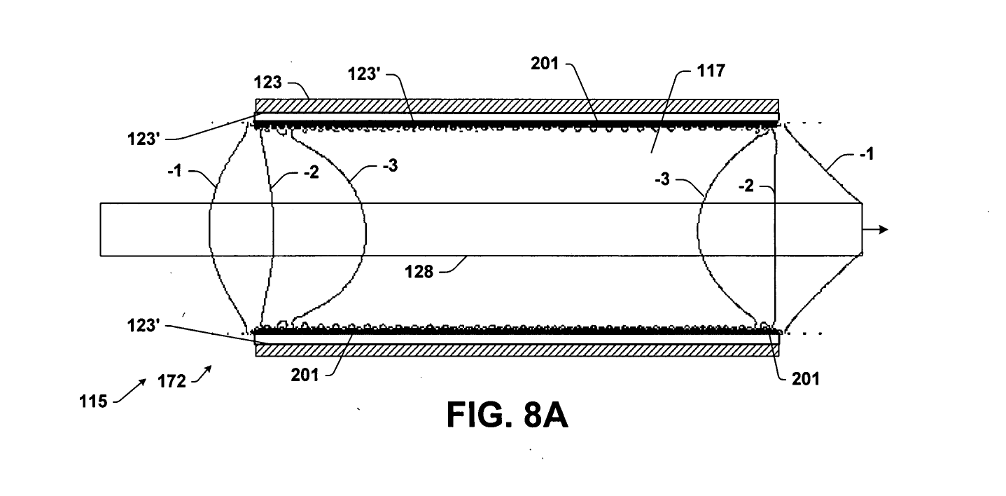

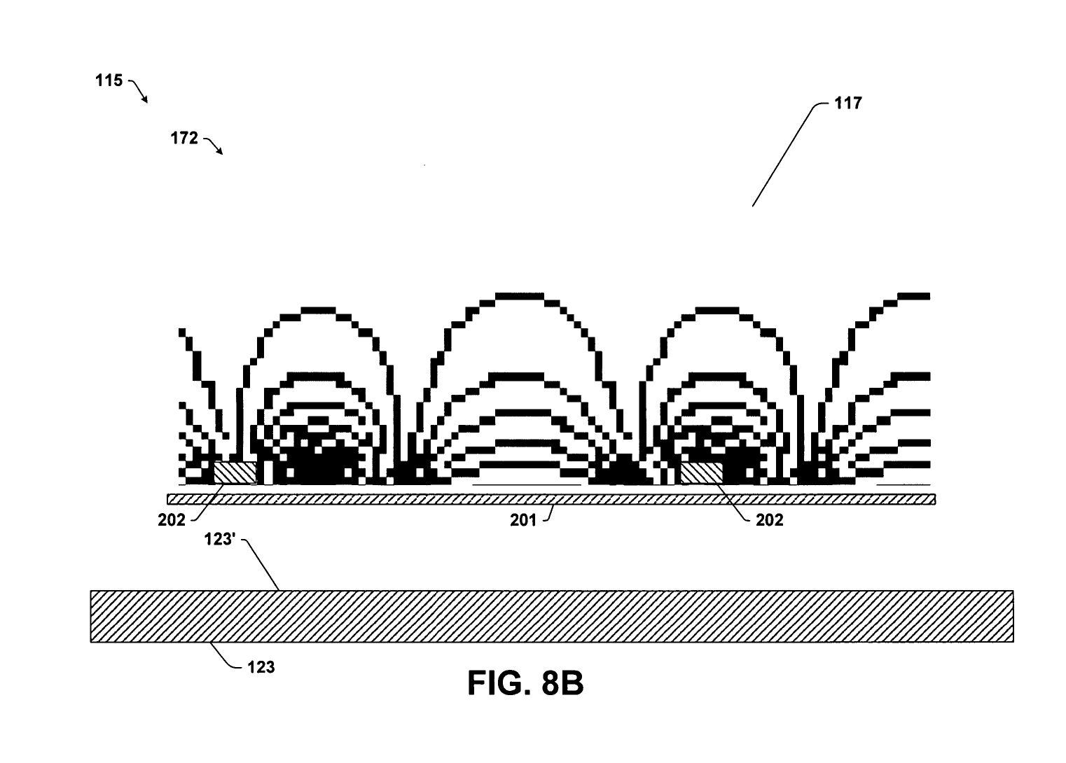

In FIG. 7A, the apparatus 172 repels electrons away from four sidewalls 123, where the negatively biased first conductive member 201 is generally continuous around the lateral periphery of the passageway 117, and the positively biased second member 202 extends around the periphery and is spaced inwardly from the first member 201 for localization of the field effect seen by the ion beam 128. In FIG. 7B, the apparatus 172 repels electrons away from the upper and lower sidewalls 123 in the resolver 115, wherein FIGS. 8A and 8B illustrate further details of this implementation of the apparatus 172 and associated electrostatic fields using a second conductive member 202 comprising a plurality of parallel wires 202 (e.g., as in FIG. 4D above) and exemplary localized electrostatic fields associated therewith. FIG. 7C illustrates another possible implementation in which the first member 201 is negatively biased, and the second member 202 is positively biased for repelling electrons away from the upper housing sidewall 123, and FIG. 7D illustrates another approach with the beam containment apparatus 172 encircling beam 128.

As illustrated in FIGS. 8A and 8B, this example provides ‘cusp’ type negative voltage fields in the apparatus 172 that are localized to the region of the passageway 117 near the sidewalls 123 essentially throughout the length of the apparatus 172, wherein the fields near the entrance and exit ends (FIG. 8A) are much smaller than in the example of FIGS. 6A and 6B above. Thus, in this example and that of FIGS. 5A-5C, the beam ions entering the apparatus 172 experience only a small acceleration of about 3 volts, and then are only slightly decelerated as they exit the apparatus 172. Furthermore, as with the above examples, the implementations of FIGS. 7A-8B provide for the electrostatic field strength at the beam 128 to be significantly smaller than that near the second conductive member 202, wherein the electrostatic field at the ion beam in the mid portion of the apparatus 172 is about 0.1 V/cm or less. The structure and biasing values illustrated in FIGS. 7A-7D are merely examples, wherein other biasing values and dimensions may be employed within the scope of the invention, wherein these values may be adjusted for a given passageway size, or to tune other operational performance measures.

FIGS. 9A-9C illustrate alternative implementations in which the first conductive member 201 is omitted, wherein the fields are localized by grounding the housing 123. As with the above implementations, the second conductive member 202 covers at least a first portion of the first conductive member 201 or the housing sidewall inner surfaces 123′ and exposes at least a second portion thereof to the ion beam 128.

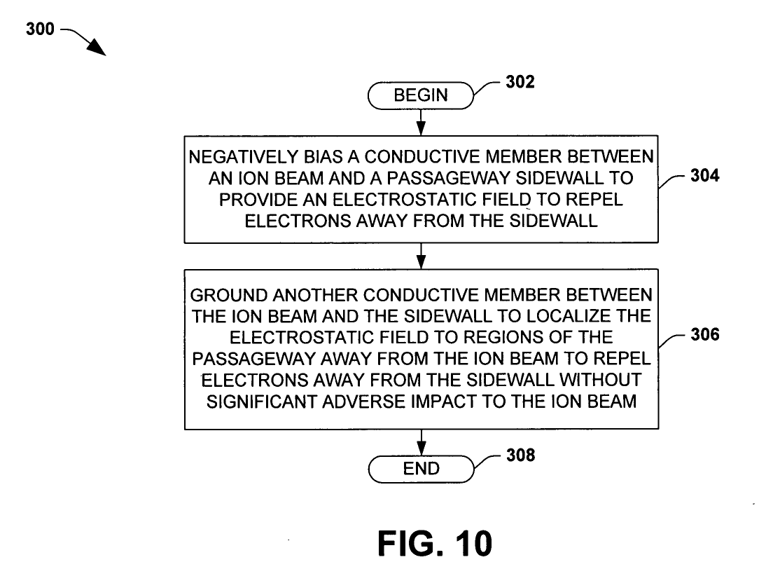

Referring now to FIG. 10, another aspect of the invention provides methods for inhibiting electron loss to a sidewall in an ion beam transport passageway, which may be implemented in the structures illustrated herein and/or in association with other systems and apparatus. An exemplary method 300 is illustrated in the flow diagram of FIG. 10 in accordance with this aspect of the invention. Although the exemplary method 300 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the systems and apparatus illustrated and described herein as well as in association with other devices not illustrated.

Beginning at 302, the method 300 comprises providing an electrostatic field in a beam passageway to repel electrons away from a passageway sidewall by negatively biasing a conductive member between an ion beam and the sidewall. At 306, another conductive member between the ion beam and the sidewall is grounded to localize the electrostatic field to regions of the passageway away from an ion beam, so as to repel electrons away from the sidewall without significant adverse impact to the ion beam. The electrostatic field localization at 306 in one implementation comprises localizing the electrostatic field to be about two orders of magnitude smaller or less at the ion beam relative to that near the biased conductive member. This is accomplished in the above-illustrated examples by having the second conductive member 202 in very close proximity to the first conductive member 201, in order to cancel the field in a short distance. In this fashion, the field is made sufficiently strong near the biased member to repel electrons away from the passageway sidewalls, while avoiding or minimizing adverse impact on the beam, wherein the exemplary method 300 then ends at 308. Alternative implementations are of course possible, for example, wherein the other conductive member at 306 may be held at a potential other than ground.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. An ion implantation system, comprising:
an ion source adapted to produce an ion beam along a path;
a beamline assembly located downstream from the ion source, the beamline assembly comprising at least one sidewall having an interior surface spaced from the path and defining a passageway through which the ion beam is transported along the path;
an end station located downstream from the beamline assembly along the path, the beamline assembly receiving the ion beam from the ion source along the path and directing ions of a desired charge-to-mass ratio along the path toward the end station, and the end station being adapted to support a wafer along the path for implantation using the ion beam; and
a beam containment apparatus to inhibit electron loss to the sidewall along at least a portion of the path, the beam containment apparatus comprising:
a first conductive member extending along at least a portion of the passageway, the first conductive member being spaced inwardly from the interior surface toward the ion beam and spaced from the ion beam between the sidewall interior surface and the ion beam;
a second conductive member located within the passageway along the portion of the passageway between the first conductive member and the ion beam, the second conductive member being proximate to and covering at least a first portion of the first conductive member and exposing at least a second portion of the first conductive member to the ion beam; and
a power source coupled with one of the first and second conductive members, the power source providing a first voltage to the one of the first and second conductive members to create an electrostatic field within the passageway;
wherein the other of the first and second conductive members is held at a second voltage greater than the first voltage to substantially localize the electrostatic field to regions of the passageway away from the ion beam so as to repel electrons away from the sidewall without significant adverse impact to the ion beam.

2. The system of claim 1, wherein the second conductive member comprises at least one opening exposing the second portion of the first conductive member to the ion beam.

3. The system of claim 1, wherein the beamline assembly comprises a mass analyzer adapted to receive the ion beam from the ion source and to direct ions of the desired charge-to-mass ratio along the path toward the end station, and wherein the first and second conductive members are located within the mass analyzer.

4. The system of claim 1, wherein the beamline assembly comprises a mass analyzer adapted to receive the ion beam from the ion source and to direct ions of the desired charge-to-mass ratio along the path toward the end station, and wherein the first and second conductive members are located downstream of the mass analyzer.

5. The system of claim 4, wherein the beamline assembly further comprises a resolver downstream of the mass analyzer, and wherein the first and second conductive members are located within the resolver.

6. The system of claim 1, wherein at least one of the first and second conductive members comprises graphite.

7. The system of claim 1, wherein the power source is coupled with the first conductive member and provides the first voltage to the first conductive member to create the electrostatic field within the passageway, and wherein the second conductive member is held at the second voltage to substantially localize the electrostatic field to regions of the passageway away from the ion beam.

8. The system of claim 7, wherein the second conductive member comprises at least one opening exposing the second portion of the first conductive member to the ion beam.

9. The system of claim 8, wherein the second conductive member comprises a mesh structure having a first set of mutually parallel conductive wires spaced from one another and a second set of mutually parallel conductive wires spaced from one another, the first and second sets of conductive wires being generally perpendicular to one another, wherein the at least one opening comprises a plurality of generally rectangular openings between adjacent conductive wires in the mesh structure.

10. The system of claim 8, wherein the at least one opening comprises a plurality of generally circular holes through the second conductive member, the holes individually exposing portions of the first conductive member to the ion beam.

11. The system of claim 8, wherein the at least one opening comprises a plurality of elongated slots through the second conductive member, the slots individually exposing portions of the first conductive member to the ion beam.

12. The system of claim 11, wherein the individual slots have a width of about 5 mm and a length greater than the width, wherein the plurality of elongated slots are generally parallel to one another, and wherein adjacent slots are spaced from one another by about 50 mm or more.

13. The system of claim 1, wherein the power source is coupled with the second conductive member and provides the first voltage to the second conductive member to create the electrostatic field within the passageway, and wherein the first conductive member is held at the second voltage to substantially localize the electrostatic field to regions of the passageway away from the ion beam.

14. The system of claim 13, wherein the second conductive member comprises at least one opening exposing the second portion of the first conductive member to the ion beam.

15. The system of claim 14, wherein the second conductive member comprises a mesh structure having a first set of mutually parallel conductive wires spaced from one another and a second set of mutually parallel conductive wires spaced from one another, the first and second sets of conductive wires being generally perpendicular to one another, wherein the at least one opening comprises a plurality of generally rectangular openings between adjacent conductive wires in the mesh structure.

16. The system of claim 14, wherein the second conductive member comprises a set of mutually parallel conductive wires spaced from one another, wherein the at least one opening comprises a plurality of gaps between adjacent conductive wires in the set.

17. The system of claim 16, wherein the conductive wires have a wire width dimension, and wherein the conductive wires are spaced from the first conductive member by about 1 wire width dimension or less.

18. The system of claim 17, wherein the wire width dimension is about 1 mm, and wherein the conductive wires are spaced from the first conductive member by about 1 mm or less.

19. The system of claim 1, wherein the electrostatic field at the ion beam is about 0.1 V/cm or less.

20. The system of claim 1, wherein the first voltage is negative and the second voltage is ground.

21. The system of claim 1, wherein the electrostatic field at the ion beam is about two orders of magnitude smaller or less relative to that near the second conductive member.

22. The system of claim 1, wherein the power source is coupled with the first conductive member and provides the negative voltage to the first conductive member.

23. The system of claim 22, further comprising a second power source coupled with the second conductive member, the second power source providing a positive voltage to the second conductive member.

24. The system of claim 23, wherein the at least one sidewall is grounded.

25. The system of claim 23, wherein the second conductive member comprises at least one opening exposing the second portion of the first conductive member to the ion beam.

26. The system of claim 25, wherein the second conductive member comprises a mesh structure having a first set of mutually parallel conductive wires spaced from one another and a second set of mutually parallel conductive wires spaced from one another, the first and second sets of conductive wires being generally perpendicular to one another, wherein the at least one opening comprises a plurality of generally rectangular openings between adjacent conductive wires in the mesh structure.

27. The system of claim 25, wherein the at least one opening comprises a plurality of generally circular holes through the second conductive member, the holes individually exposing portions of the first conductive member to the ion beam.

28. The system of claim 25, wherein the at least one opening comprises a plurality of elongated slots through the second conductive member, the slots individually exposing portions of the first conductive member to the ion beam.

29. The system of claim 28, wherein the individual slots have a width of about 5 mm and a length greater than the width, wherein the plurality of elongated slots are generally parallel to one another, and wherein adjacent slots are spaced from one another by about 50 mm or more.

30. The system of claim 22, wherein the at least one sidewall is grounded.

31. The system of claim 30, wherein the second conductive member is grounded.

32. The system of claim 22, wherein the second conductive member is grounded.

33. Beam confinement apparatus for inhibiting electron loss to a sidewall in an ion beam transport passageway, the confinement apparatus comprising:
a first conductive member extending along at least a portion of the passageway, the first conductive member being spaced inwardly from an interior surface of the sidewall toward an ion beam and spaced from the ion beam between the sidewall interior surface and the ion beam; and
a second conductive member located within the passageway along the portion of the passageway between the first conductive member and the ion beam, the second conductive member being proximate to and covering at least a first portion of the first conductive member and exposing at least a second portion of the first conductive member to the ion beam;
wherein one of the first and second conductive members is negatively biased relative to the other of the first and second conductive members to produce an electrostatic field substantially localized to regions of the passageway away from the ion beam so as to repel electrons away from the sidewall without significant adverse impact to the ion beam.

34. The apparatus of claim 33, further comprising a power source coupled with the negatively biased conductive member, the power source providing a negative voltage to the negatively biased conductive member to create the electrostatic field within the passageway.

35. The apparatus of claim 33, wherein at least one of the first and second conductive members comprises graphite.

36. The apparatus of claim 33, wherein the first conductive member is negatively biased to create the electrostatic field within the passageway, and wherein the second conductive member is grounded to substantially localize the electrostatic field to regions of the passageway away from the ion beam.

37. The apparatus of claim 36, wherein the second conductive member comprises at least one opening exposing the second portion of the first conductive member to the ion beam.

38. The apparatus of claim 37, wherein the second conductive member comprises a mesh structure having a first set of mutually parallel conductive wires spaced from one another and a second set of mutually parallel conductive wires spaced from one another, the first and second sets of conductive wires being generally perpendicular to one another, wherein the at least one opening comprises a plurality of generally rectangular openings between adjacent conductive wires in the mesh structure.

39. The apparatus of claim 37, wherein the at least one opening comprises a plurality of generally circular holes through the second conductive member, the holes individually exposing portions of the first conductive member to the ion beam.

40. The apparatus of claim 37, wherein the at least one opening comprises a plurality of elongated slots through the second conductive member, the slots individually exposing portions of the first conductive member to the ion beam.

41. The apparatus of claim 40, wherein the individual slots have a width of about 5 mm and a length greater than the width, wherein the plurality of elongated slots are generally parallel to one another, and wherein adjacent slots are spaced from one another by about 50 mm or more.

42. The apparatus of claim 33, wherein the second conductive member is negatively biased to create the electrostatic field within the passageway, and wherein the first conductive member is grounded to substantially localize the electrostatic field to regions of the passageway away from the ion beam.

43. The apparatus of claim 42, wherein the second conductive member comprises at least one opening exposing the second portion of the first conductive member to the ion beam.

44. The apparatus of claim 43, wherein the second conductive member comprises a mesh structure having a first set of mutually parallel conductive wires spaced from one another and a second set of mutually parallel conductive wires spaced from one another, the first and second sets of conductive wires being generally perpendicular to one another, wherein the at least one opening comprises a plurality of generally rectangular openings between adjacent conductive wires in the mesh structure.

45. The apparatus of claim 43, wherein the second conductive member comprises a set of mutually parallel conductive wires spaced from one another, wherein the at least one opening comprises a plurality of gaps between adjacent conductive wires in the set.

46. The apparatus of claim 45, wherein the conductive wires have a wire width dimension, and wherein the conductive wires are spaced from the first conductive member by about 1 wire width dimension or less.

47. The apparatus of claim 46, wherein the wire width dimension is about 1 mm, and wherein the conductive wires are spaced from the first conductive member by about 1 mm or less.

48. The apparatus of claim 33, wherein the electrostatic field at the ion beam is about two orders of magnitude smaller or less relative to that near the second conductive member.

49. The apparatus of claim 33, comprising a power source coupled with the first conductive member that provides a negative voltage to the first conductive member.

50. The apparatus of claim 49, further comprising a second power source coupled with the second conductive member, the second power source providing a positive voltage to the second conductive member.

51. The apparatus of claim 50, wherein the at least one sidewall is grounded.

52. The apparatus of claim 50, wherein the second conductive member comprises at least one opening exposing the second portion of the first conductive member to the ion beam.

53. The apparatus of claim 52, wherein the second conductive member comprises a mesh structure having a first set of mutually parallel conductive wires spaced from one another and a second set of mutually parallel conductive wires spaced from one another, the first and second sets of conductive wires being generally perpendicular to one another, wherein the at least one opening comprises a plurality of generally rectangular openings between adjacent conductive wires in the mesh structure.

54. The apparatus of claim 52, wherein the at least one opening comprises a plurality of generally circular holes through the second conductive member, the holes individually exposing portions of the first conductive member to the ion beam.

55. The apparatus of claim 52, wherein the at least one opening comprises a plurality of elongated slots through the second conductive member, the slots individually exposing portions of the first conductive member to the ion beam.

56. The apparatus of claim 55, wherein the individual slots have a width of about 5 mm and a length greater than the width, wherein the plurality of elongated slots are generally parallel to one another, and wherein adjacent slots are spaced from one another by about 50 mm or more.

57. The apparatus of claim 49, wherein the at least one sidewall is grounded,.

58. The apparatus of claim 57, wherein the second conductive member is grounded.

59. The apparatus of claim 49, wherein the second conductive member is grounded.

60. Beam confinement apparatus for inhibiting electron loss to a sidewall in an ion beam transport passageway, the confinement apparatus comprising:
a conductive member extending along at least a portion of the passageway, the first conductive member being spaced inwardly from an interior surface of the sidewall toward an ion beam and spaced from the ion beam between the sidewall interior surface and the ion beam, the conductive member being proximate to and covering at least a first portion of the interior surface of the sidewall and exposing at least a second portion of the interior surface of the sidewall to the ion beam;
wherein the conductive member is biased at a different voltage than the sidewall.

61. The apparatus of claim 60, wherein the conductive member is negatively biased with respect to the sidewall.

62. A method of inhibiting electron loss to a sidewall in an ion beam transport passageway, the method comprising:
providing an electrostatic field in the passageway to repel electrons away from the sidewall; and
localizing the electrostatic field to regions of the passageway away from an ion beam so as to repel electrons away from the sidewall without significant adverse impact to the ion beam.

63. The method of claim 62, wherein providing the electrostatic field comprises negatively biasing a conductive member between the ion beam and the sidewall, and wherein localizing the electrostatic field comprises grounding another conductive member between the ion beam and the sidewall.

64. The method of claim 63, wherein localizing the electrostatic field comprises localizing the electrostatic field to be about two orders of magnitude smaller or less at the ion beam relative to that near the biased conductive member.

65. The method of claim 62, wherein localizing the electrostatic field comprises localizing the electrostatic field to be about two orders of magnitude smaller or less at the ion beam relative to that near the biased conductive member.
